(19) United States
(12) Patent Application Publication
(10) Pub. No.: US 2026/0146211 A1
(43) Pub. Date: May 28, 2026

(54) POST-CHEMICAL MECHANICAL POLISHING CLEANING COMPOSITION, METHOD FOR POST-CHEMICAL MECHANICAL POLISHING CLEANING TREATMENT, AND METHOD FOR PRODUCING SEMICONDUCTOR SUBSTRATE

(71) Applicant: FUJIMI INCORPORATED, Aichi (JP)

(72) Inventor: Emi Narita, Aichi (JP)

(21) Appl. No.: 19/330,286

(22) Filed: Sep. 16, 2025

(30) Foreign Application Priority Data
Sep. 27, 2024 (JP) 2024-168596

(51) Int. Cl. C11D 1/66; C11D 1/12; C11D 1/83

(52) U.S. Cl. CPC C11D 1/66; C11D 1/12; C11D 1/123; C11D 1/83

(57) ABSTRACT

Provided is means that enables removing residues remaining on the surface of a polished object containing silicon-containing material sufficiently. A post-chemical mechanical polishing cleaning composition, containing a sulfonic acid group-containing anionic polymer and a nitrogen-containing nonionic polymer having a weight-average molecular weight of 2,000 or more and 20,000 or less.

### TECHNICAL FIELD

The present invention relates to a post-chemical mechanical polishing cleaning composition, a method for post-chemical mechanical polishing cleaning treatment, and a method for producing a semiconductor substrate.

### BACKGROUND ART

In recent years, a so-called chemical mechanical polishing (CMP) technique for physically polishing and flattening a semiconductor substrate in producing a device is used in accordance with multilayer wiring on a surface of a semiconductor substrate. CMP is a method for flattening a surface of an object to be polished (polishing object) such as a semiconductor substrate using a polishing composition (slurry) containing abrasive grains such as silica, alumina, or ceria, an anti-corrosion agent, a surfactant, or the like. The object to be polished (polishing object) is a silicon-containing material such as silicon, polysilicon, silicon oxide, silicon nitride, a wiring or a plug which consists of metal, or the like.

On a surface of a semiconductor substrate after the CMP step, impurities (also referred to as foreign matter or residues) remain in a large amount. Impurities include abrasive grains, metals, an anti-corrosion agent and organic matter such as a surfactant, which are derived from a polishing composition used for CMP, a silicon-containing material or a metal which is generated by polishing of a silicon-containing material, metal wiring, a plug or the like as an object to be polished, and also organic matter such as pad debris which is generated from various pads.

Once a surface of a semiconductor substrate is contaminated with these impurities, the electrical properties of the semiconductor may be adversely affected, so as to lower device reliability. Hence, it is desired to remove these impurities from the surface of a semiconductor substrate by introducing a cleaning step following the CMP step.

For example, Japanese Patent Laid-Open No. 2020-167237 discloses a rinse composition for silicon wafers containing a water-soluble polymer that satisfies specific conditions as such a cleaning composition, and discloses that this can remove foreign matter on silicon wafers after polishing and reduce defects on the silicon wafers after the polishing.

### SUMMARY OF INVENTION

However, the technique of Japanese Patent Laid-Open No. 2020-167237 is problematic in that foreign matter (residues) cannot be sufficiently removed in the cleaning of a polished object containing silicon-containing material.

Therefore, an object of the present invention is to provide means capable of sufficiently removing residues remaining on a surface of a polished object containing silicon-containing material.

The inventors of the present invention have intensively studied in view of the above problem. As a result, the inventors of the present invention have discovered that the above problem may be solved by a post-chemical mechanical polishing cleaning composition comprising a sulfonic acid group-containing anionic polymer and a nitrogen-containing nonionic polymer having a weight-average molecular weight of 2,000 or more and 20,000 or less and thus have completed the present invention.

### DESCRIPTION OF EMBODIMENTS

An embodiment of the present invention is a post-chemical mechanical polishing cleaning composition comprising a sulfonic acid group-containing anionic polymer and a nitrogen-containing nonionic polymer having a weight-average molecular weight of 2,000 or more and 20,000 or less.

Hereinafter, the post-chemical mechanical polishing cleaning composition as used herein is also referred to as a “post-chemical mechanical polishing cleaning composition according to the present embodiment”, a “post-CMP cleaning composition”, or a “post-CMP cleaning composition according to the present embodiment”.

According to such a post-chemical mechanical polishing cleaning composition (post-CMP cleaning composition), residues (for example, abrasive grain residues (especially silicon compounds) and organic residues) remaining on the surface of a polished object, especially a polished object containing silicon-containing material such as silicon nitride, silicon oxide, or polysilicon, can be sufficiently removed. That is, the present invention provides means that enables removing residues remaining on the surface of a polished object containing a silicon-containing material sufficiently.

Note that the term “polished object” used herein refers to an object to be polished that has been polished with the polishing composition. In the present invention, the polished object contains silicon-containing material. The term “polished object containing silicon nitride” means that the polished object has a film (layer) containing silicon nitride. The term “polished object containing silicon oxide” means that the polished object has a film (layer) containing silicon oxide. The term “polished object containing polysilicon” means that the polished object has a film (layer) containing polysilicon. That is, the polished object according to the present embodiment has a silicon-containing material such as silicon nitride, silicon oxide and polysilicon. Hereinafter, “the polished object containing silicon-containing material” may be referred to merely as the “polished object”.

When the post-CMP cleaning composition has the above configuration, this facilitates adsorbing the nitrogen-containing nonionic polymer and the sulfonic acid group-containing anionic polymer to the polished object more efficiently. It is believed that this can suppress the re-adhesion of residues (contaminants such as abrasive grain residues and/or organic residues) to the surface of the polished object while desorbing the residues on the surface of the polished object more efficiently. The inventor of the present invention infers a specific mechanism of removing residues on the surface of the polished object with the above configuration, as follows.

The sulfonic acid groups in the sulfonic acid group-containing anionic polymer release hydrogen ions (H⁺) even in a solution at a low pH (for example, in a solution at a pH of 2 to 4) to be ionized (R—SO₃⁻). Consequently, the sulfonic acid group-containing anionic polymer can adsorb to the surfaces of the polished object and abrasive grain residues, and both the zeta potentials of these are negatively controlled (negatively charged). This enables leading to the electrostatic repulsion between the polished object and the abrasive grain residues to desorb the abrasive grain residues from the polished object efficiently, further suppressing the re-adhesion to the polished object. The sulfonic acid group-containing anionic polymer easily adsorbs to a film containing silicon nitride, and can suitably exhibit the above effect on the film containing the silicon nitride.

The nitrogen-containing nonionic polymer is satisfactorily compatible with hydrophobic substances due to the intermolecular interaction and the hydrophobic interaction. The nitrogen-containing nonionic polymer therefore adsorbs to the surface of the hydrophobic polished object (for example, a film containing silicon oxide and/or a film containing polysilicon) to act so as to desorb organic residues from the polished object efficiently.

The inventor of the present invention has however found a trade-off relationship as follows: while the nitrogen-containing nonionic polymer can act to reduce organic residues, abrasive grain residues are likely to remain. Accordingly, the inventor of the present invention has noticed that the contained nitrogen-containing nonionic polymer inhibits the sulfonic acid group-containing anionic polymer from exhibiting the effect of reducing abrasive grain residues.

Accordingly, the inventor of the present invention has examined means for satisfying both requirements in a trade-off relationship, namely means that enables reducing both abrasive grain residues and organic residues. Consequently, the inventor has found that the weight-average molecular weight of the nitrogen-containing nonionic polymer affects the zeta potential of the polished object (for example, a film containing silicon nitride) to be negatively charged by the sulfonic acid group-containing anionic polymer. The inventor of the present invention has inferred that this phenomenon is caused in the following mechanism: The nitrogen-containing nonionic polymer adsorbs to the sulfonic acid group-containing anionic polymer to affect the negative charge of the sulfonic acid group-containing anionic polymer, resulting in influence on negatively charging the polished object. The inventor of the present invention has found that as the weight-average molecular weight of the nitrogen-containing nonionic polymer decreases, the nitrogen-containing nonionic polymer is less likely to inhibit the sulfonic acid group-containing anionic polymer from negatively charging the polished object. However, the inventor has confirmed that as the weight-average molecular weight of the nitrogen-containing nonionic polymer decreases, the nitrogen-containing nonionic polymer deteriorates in action of adsorbing to hydrophobic substances (for example, a hydrophobic polished object) to decline the effect of reducing organic residues. As a result of such earnest studies, the inventor of the present invention has found that if the nitrogen-containing nonionic polymer has a weight-average molecular weight of 2,000 or more and 20,000 or less, this enables maintaining the effect of reducing abrasive grain residues and also enables the nitrogen-containing nonionic polymer to maintain the effect of reducing organic residues.

Furthermore, when the above configuration is set, the components (the nitrogen-containing nonionic polymer and the sulfonic acid group-containing anionic polymer) adsorbed to the surface of the polished object can also be easily desorbed from the surface of the polished object, and this enables the components themselves adsorbed to the surface of the polished object hardly or not to remain as residues. It is believed from the above that the post-CMP cleaning composition of the present invention can sufficiently remove residues.

Note that the above mechanism is based on the inference, and the present invention is not limited by the above mechanism.

The embodiments of the present invention will be described below in detail, but the present invention is not limited to the following embodiments alone. The embodiments can be variously modified within the claims. Optional combination of the embodiments described herein enables the production of other embodiments. In addition, in this specification, unless otherwise specified, operation and measurement of physical properties, etc., are performed under conditions of room temperature (20° C. or higher and 25° C. or lower)/relative humidity of 40% RH or more and 50% RH or less.

### <Residue>

The term “residue(s)” used herein refers to foreign matter adhered to a surface of a polished object. Examples of a residue include, but are not particularly limited to, later-described organic residues, particle residues derived from abrasive grains contained in a polishing composition, residues composed of components other than particle residues, and organic residues, and other residues such as mixtures of particle residues and organic residues.

The term “organic residue(s)” used herein represents, among foreign matter adhered to a surface of a polished object (object to be subjected to surface treatment), components comprising organic matters, organic salts, and the like such as organic low molecular weight compounds and polymer compounds.

Examples of organic residues adhered to a polished object include pad debris that are generated from pads used in later-described polishing step or rinse polishing step, or components derived from additives contained in polishing compositions that are used in the polishing step or post-CMP cleaning compositions used in the rinse polishing step.

Note that since organic residues and other foreign matter may be significantly different from each other in terms of color and shape, whether or not the foreign matter is an organic residue can be visually confirmed by SEM observation. Whether or not foreign matter is an organic residue can be determined as necessary by elementary analysis using energy-dispersive X-ray spectroscopy (EDX). The number of organic residues can be measured using a wafer defect inspection apparatus and SEM or EDX elementary analysis.

### <Polished Object>

The term “polished object” used herein refers to an object to be polished that has been polished in a polishing step. The polishing step is a CMP step.

The polished object (object to be polished) according to the present embodiment contains silicon-containing material, for example, at least one selected from the group consisting of silicon nitride (Si₃N₄), silicon oxide (SiO₂), and polysilicon (polycrystalline silicon). In an embodiment, the polished object (object to be polished) contains silicon nitride (Si₃N₄), silicon oxide (SiO₂), and polysilicon (polycrystalline silicon). According to another embodiment, the polished object (object to be polished) according to the present embodiment contains at least one selected from the group consisting of silicon nitride (Si₃N₄) and polysilicon (polycrystalline silicon).

As long as the object to be polished according to the present embodiment contains silicon-containing material, for example, at least one selected from the group consisting of silicon nitride (Si₃N₄), silicon oxide (SiO₂), and polysilicon (polycrystalline silicon), material contained in the object to be polished according to the present embodiment is not particularly limited. For example, the object to be polished may further contain carbon-containing silicon such as silicon carbonitride (SiCN); non-crystalline silicon (amorphous silicon); silicon material doped with impurities; metal simple substances; alloys; metal nitrides; and compound semiconductors such as SiGe.

Examples of a silicon oxide-containing film include a TEOS (Tetraethyl Orthosilicate)-type silicon oxide film (hereinafter may also be simply referred to as “TEOS film”) that is formed using tetraethyl orthosilicate as a precursor, an HDP (High Density Plasma) film, an USG (Undoped Silicate Glass) film, a PSG (Phosphorus Silicate Glass) film, a BPSG (Boron-Phospho Silicate Glass) film, and an RTO (Rapid Thermal Oxidation) film. The silicon oxide-containing film contained in the polished object may be of only one type or of two or more types in combination.

The polished object is a polished semiconductor substrate, and is preferably a semiconductor substrate after the CMP step. The reason for this is that residues can result in a defective semiconductor device. When a polished object is a polished semiconductor substrate, a step for cleaning the semiconductor substrate is required to be able to remove residues as far as possible.

Further, the post-CMP cleaning composition according to an embodiment of the present invention can reduce residues on the surface of even a polished object containing both a hydrophilic material and a hydrophobic material. Here, the term “hydrophilic material” refers to a material having a contact angle with respect to water of less than 50°, and the term “hydrophobic material” refers to a material having a contact angle with respect to water of 50° or more. Note that the contact angle with respect to water is a value measured using a contact angle meter, Drop Master (manufactured by Kyowa Interface Science Co., Ltd., DMo-501).

Specific examples of the hydrophilic material include silicon oxide, silicon nitride, silicon oxynitride, tungsten, titanium nitride, tantalum nitride, and boron-containing silicon. These hydrophilic materials may be used singly or in combinations of two or more thereof. According to a preferred embodiment of the present invention, the above hydrophilic material is silicon nitride. According to a preferred embodiment of the present invention, the above hydrophilic material is silicon nitride and silicon oxide. Further, specific examples of the hydrophobic material include polysilicon (polycrystalline silicon), single crystal silicon, non-crystalline silicon, and carbon-containing silicon. These hydrophobic materials may be used singly or in combinations of two or more thereof. According to a preferred embodiment of the present invention, the hydrophobic material is polysilicon (polycrystalline silicon).

That is, according to a preferred embodiment of the present invention, the above hydrophilic material is silicon nitride, and the above hydrophobic material is polysilicon (polycrystalline silicon). Further, according to a preferred embodiment of the present invention, the above hydrophilic material is silicon nitride and silicon oxide, and the above hydrophobic material is polysilicon (polycrystalline silicon).

### <Post-Chemical Mechanical Polishing Cleaning Composition (Post-CMP Cleaning Composition)>

The post-chemical mechanical polishing cleaning composition (post-CMP cleaning composition) according to the present embodiment contains the nitrogen-containing nonionic polymer and the sulfonic acid group-containing anionic polymer. Here, the term “polymer” used herein refers to a compound having a weight-average molecular weight (Mw) of 1,000 or more. Further, the term “nonionic polymer” used herein refers to a polymer not having an anionic group such as a carboxylic acid group, a sulfonic acid group, or a phosphoric acid group, and a cationic group such as an amino group or a quaternary ammonium group in a molecule. The term “anionic polymer” refers to a polymer having an anionic group such as a carboxylic acid group, a sulfonic acid group, and a phosphoric acid group in a molecule. Hereinafter, the polymers will be described.

### [Nitrogen-Containing Nonionic Polymer]

The nitrogen-containing nonionic polymer contained in the post-CMP cleaning composition according to the present embodiment means a nonionic polymer containing nitrogen atoms in molecules. The nitrogen-containing nonionic polymer contained in the post-CMP cleaning composition according to the present embodiment has a weight-average molecular weight of 2,000 or more and 20,000 or less. When the nitrogen-containing nonionic polymer has a weight-average molecular weight of less than 2,000, the nitrogen-containing nonionic polymer deteriorates in the action of adsorbing to hydrophobic material (for example, a hydrophobic polished object) to decline in the effect of reducing organic residues. When the nitrogen-containing nonionic polymer has a weight-average molecular weight of more than 20,000, the nitrogen-containing nonionic polymer inhibits the sulfonic acid group-containing anionic polymer from negatively charging the polished object to deteriorate the effect of reducing abrasive grain residues.

The weight-average molecular weight of the nitrogen-containing nonionic polymer is preferably 3,000 or more, more preferably 5,000 or more, further preferably 7,000 or more, further more preferably 8,000 or more, particularly preferably 8,500 or more, and the most preferably 9,000 or more. Further, the weight-average molecular weight of the nitrogen-containing nonionic polymer is preferably 18,000 or less, more preferably 15,000 or less, further preferably 14,000 or less, further more preferably 13,000 or less, particularly preferably 12,000 or less, and the most preferably 11,000 or less. That is, the weight-average molecular weight of the nitrogen-containing nonionic polymer is preferably 3,000 or more and 18,000 or less, more preferably 5,000 or more and 15,000 or less, further preferably 7,000 or more and 14,000 or less, further more preferably 8,000 or more and 13,000 or less, particularly preferably 8,500 or more and 12,000 or less, and the most preferably 9,000 or more and 11,000 or less. When the weight-average molecular weight of the nitrogen-containing nonionic polymer is within the above range, after the treatment using the post-CMP cleaning composition, residues on the surface of the polished object can be more efficiently removed, and the expected effect of the present invention is further exhibited.

The nitrogen-containing nonionic polymer only has to be a nonionic polymer having nitrogen atoms. Examples include polyamines, polyvinylpyrrolidone, polyacrylamide, poly-N-vinylacetamide, polydimethylacrylamide, polyacryloylmorpholine, poly-N-vinylcaprolactam, poly-N-isopropylacrylamide, and oxazoline group-containing polymers. As the nitrogen-containing nonionic polymer, not only those having the above main chain structures, but also graft copolymers having nonionic polymer structures in the side chains can also be suitably used. The nitrogen-containing nonionic polymer may be a polymer having the same repeating constitutional units (homopolymer) or different repeating constitutional units from each other (copolymer). The form of a copolymer when the nitrogen-containing nonionic polymer is the copolymer may be any of a block copolymer, a random copolymer, a graft copolymer, and an alternating copolymer.

The nitrogen-containing nonionic polymer is preferably a polymer having an amide bond or an oxazoline group, more preferably a polymer having an amide bond or an oxazoline group in its side chain structure, further preferably at least one selected from polyvinylpyrrolidone, poly-N-vinylacetamide, polydimethylacrylamide, polyvinyl caprolactam, N-isopropylacrylamide, or oxazoline group-containing polymers. The nitrogen-containing nonionic polymer may be used alone or in combination of two or more. As the nitrogen-containing nonionic polymer, a commercial product thereof or a synthetic product thereof may also be used.

The content of the nitrogen-containing nonionic polymer in the post-CMP cleaning composition is preferably more than 1 mass ppm, more preferably 5 mass ppm or more, further preferably 10 mass ppm or more, still more preferably 50 mass ppm or more, particularly preferably 100 mass ppm or more, and the most preferably 150 mass ppm or more with respect to the total mass of the post-CMP cleaning composition. The content of the nitrogen-containing nonionic polymer in the post-CMP cleaning composition is preferably 5 mass % (50,000 mass ppm) or less, more preferably 3 mass % (30,000 mass ppm) or less, further preferably 2 mass % (20,000 mass ppm) or less, still more preferably 1.5 mass % (15,000 mass ppm) or less, particularly preferably 1 mass % (10,000 mass ppm) or less, and the most preferably 0.5 mass % (5,000 mass ppm) or less with respect to the total mass of the post-CMP cleaning composition. That is, the content of the nitrogen-containing nonionic polymer is preferably more than 1 mass ppm and 5 mass % or less, more preferably 5 mass ppm or more and 3 mass % or less, further preferably 10 mass ppm or more and 2 mass % or less, still more preferably 50 mass ppm or more and 1.5 mass % or less, particularly preferably 100 mass ppm or more and 1 mass % or less, and the most preferably 150 mass ppm or more and 0.5 mass % or less with respect to the total mass of the post-CMP cleaning composition. When the content of the nitrogen-containing nonionic polymer is in the above range, after the treatment using the post-CMP cleaning composition, residues on the surface of the polished object can be more efficiently removed, and the expected effect of the present invention is further exhibited.

According to an embodiment, the content of the nitrogen-containing nonionic polymer in the post-CMP cleaning composition is 10 mass ppm or more and 1 mass % or less with respect to the total mass of the post-CMP cleaning composition.

When two or more types of nitrogen-containing nonionic polymers are contained in the post-CMP cleaning composition, the content of the nitrogen-containing nonionic polymer is the total amount thereof.

### [Sulfonic Acid Group-Containing Anionic Polymer]

The sulfonic acid group-containing anionic polymer contained in the post-CMP cleaning composition according to the present embodiment acts as a dispersant in the post-CMP cleaning composition. When the post-CMP cleaning composition contains the sulfonic acid group-containing anionic polymer, both zeta potentials of the surface of the polished object (e.g., a polished object containing silicon nitride) and defect sources such as abrasive grains and organic residues are negatively controlled to form electrostatic repulsion layers, so that this enables reducing the number of defects of the polished object.

The weight-average molecular weight of the sulfonic acid group-containing anionic polymer is preferably 1,500 or more, more preferably 3,000 or more, further preferably 4,000 or more, and further more preferably 5,000 or more, particularly preferably 6,000 or more, particularly more preferably 7,000 or more, and the most preferably 8,000 or more. Further, the weight-average molecular weight of the sulfonic acid group-containing anionic polymer is preferably 1,000,000 or less, more preferably 500,000 or less, further preferably 100,000 or less, further more preferably 50,000 or less, particularly preferably 25,000 or less, particularly more preferably 20,000 or less, and the most preferably 15,000 or less. That is, the weight-average molecular weight of the sulfonic acid group-containing anionic polymer is preferably 1,500 or more and 1,000,000 or less, more preferably 3,000 or more and 500,000 or less, further preferably 4,000 or more and 100,000 or less, further more preferably 5,000 or more and 50,000 or less, particularly preferably 6,000 or more and 25,000 or less, particularly more preferably 7,000 or more and 20,000 or less, and the most preferably 8,000 or more and 15,000 or less. When the weight-average molecular weight of the sulfonic acid group-containing anionic polymer is within the above range, after the treatment using the post-CMP cleaning composition, and residues on the surface of the polished object can be more efficiently removed, and the expected effect of the present invention is further exhibited.

The sulfonic acid group-containing anionic polymer only has to have sulfonic acid groups, and specific examples include polyvinyl sulfonic acid, polystyrene sulfonic acid, polyallyl sulfonic acid, polymethallyl sulfonic acid, poly(2-acrylamide-2-methylpropane sulfonic acid), polyisoprene sulfonic acid, a (meth)acrylic acid-isoprene sulfonic acid copolymer, a (meth)acrylic acid-[2-(meth)acrylamido-2-methylpropane sulfonic acid] copolymer, and a (meth)acrylic acid-isoprene sulfonic acid-[2-(meth)acrylamide-2-methylpropane sulfonic acid] copolymer. These sulfonic acid group-containing anionic polymer may have neutralized salt forms.

Furthermore, as the sulfonic acid group-containing anionic polymer, not only those having the above main chain structures, but also graft copolymers having sulfonic acid group-containing anionic polymer structures in the side chains can also be suitably used. The above sulfonic acid group-containing anionic polymer may be a polymer having the same repeating constitutional units (homopolymer) or different repeating constitutional units from each other (copolymer). The form of a copolymer when the sulfonic acid group-containing anionic polymer is the copolymer may be any of a block copolymer, a random copolymer, a graft copolymer, and an alternating copolymer. The above repeating structure of the copolymer may comprise a repeating unit having a sulfonic acid group and a repeating unit not having a sulfonic acid group, or may consist exclusively of two or more repeating structures having a sulfonic acid group.

Furthermore, the sulfonic acid group-containing anionic polymer may contain only a sulfonic acid group as the anionic group, or may contain one or more anionic groups other than a sulfonic acid group besides a sulfonic acid group.

The sulfonic acid group-containing anionic polymer may be used alone or in combination of two or more. When the post-CMP cleaning composition contain two or more sulfonic acid group-containing anionic polymers, the content of the sulfonic acid group-containing anionic polymers is the total amount thereof. As the sulfonic acid group-containing anionic polymer, a commercial product thereof or a synthetic product thereof may also be used.

Although the content of the sulfonic acid group-containing anionic polymer in the post-CMP cleaning composition is not particularly limited, the content is preferably more than 0.0002 mass ppm and 2 mass % or less, more preferably 0.001 mass ppm or more and 1 mass % or less, further preferably 0.005 mass ppm or more and 5,000 mass ppm or less, still more preferably more than 0.01 mass ppm and 2,500 mass ppm or less, particularly preferably 0.05 mass ppm or more and 2,000 mass ppm or less, and the most preferably 0.1 mass ppm or more and 1,500 mass ppm or less with respect to the total mass of the post-CMP cleaning composition. According to an embodiment, the content of the sulfonic acid group-containing anionic polymer is 0.1 mass ppm or more and 1000 mass ppm or less. When the content of the sulfonic acid group-containing anionic polymer is in the above range, after the treatment using the post-CMP cleaning composition, residues on the surface of the polished object can be more efficiently removed, and the expected effect of the present invention is further exhibited.

### [Other Polymers]

The post-CMP cleaning composition according to the present embodiment may further contain another polymer (other polymer) other than the above nitrogen-containing nonionic polymer and sulfonic acid group-containing anionic polymer. As the other polymer, any of a cationic polymer, an amphoteric polymer, a nitrogen-free nonionic polymer, and a sulfonic acid group-free anionic polymer can be used. Further, the other polymer is preferably a water-soluble polymer. The water-soluble polymer used here refers to a water-soluble polymer having the same repeating constitutional units (homopolymer) or a water-soluble polymer having different repeating constitutional units from each other (copolymer), and is typically a compound having a weight-average molecular weight (Mw) of 1000 or more.

Examples of the cationic polymer include polyethylenimine (PEI), polyvinyl amine, polyallyl amine, polyvinyl pyridine, and cationic acrylamide polymers.

Examples of the amphoteric polymer include a copolymer of a vinyl monomer having an anionic group and a vinyl monomer having a cationic group, and an amphoteric vinyl polymer having a carboxybetaine group or a sulfobetaine group. Specific examples thereof include an acrylic acid/dimethylaminoethyl methacrylic acid copolymer, and an acrylic acid/diethylaminoethyl methacrylic acid copolymer.

Although the nitrogen-free nonionic polymer only has to be a nonionic polymer having no nitrogen atoms, the nitrogen-free nonionic polymer is preferably a nonionic polymer having no nitrogen atoms and having oxygen atoms. Examples of the nitrogen-free nonionic polymer include polyvinyl alcohol; polyvinyl ethers (polyvinyl methyl ether, polyvinyl ethyl ether, polyvinyl isobutyl ether, etc.); polyalkylene oxides (polyethylene oxide, polypropylene oxide, polybutylene oxide, etc.); polyglycerol; polyethylene glycol; polypropylene glycol; polybutylene glycol; water-soluble polysaccharides such as hydroxyethyl cellulose; alginic acid polyhydric alcohol esters; and dextrin derivatives.

In an embodiment, the content of the above other polymer other than the nitrogen-containing nonionic polymer and sulfonic acid group-containing anionic polymer is not particularly limited, but is, for example, 0.15 mass % or less, preferably 0.10 mass % or less, more preferably less than 0.10 mass %, and further preferably 0.05 mass % or less with respect to the entire post-CMP cleaning composition. When the post-CMP cleaning composition contains the above two or more other polymers other than the nitrogen-containing nonionic polymer and the sulfonic acid group-containing anionic polymer, the content thereof is the total amount thereof. In an embodiment, the post-CMP cleaning composition according to the present embodiment may not contain the above other polymer other than the nitrogen-containing nonionic polymer and the sulfonic acid group-containing anionic polymer. The post-CMP cleaning composition according to the present embodiment may contain the nitrogen-free nonionic polymer, or may not contain the nitrogen-free nonionic polymer. It is preferable from the viewpoint that the effect of the nitrogen-containing nonionic polymer is further exhibited that the post-CMP cleaning composition according to the present embodiment do not contain the nitrogen-free nonionic polymer.

### [Solvent]

The post-CMP cleaning composition according to the present embodiment preferably contain a solvent. A solvent has a function of dispersing or dissolving each component. The solvent preferably contains water, and more preferably contain water alone. Further, the solvent may also be a mixed solvent of water and an organic solvent in order to disperse or dissolve each component. In this case, examples of an organic solvent to be used herein include water-miscible organic solvents such as acetone, acetonitrile, ethanol, methanol, isopropanol, glycerin, ethylene glycol, and propylene glycol. Moreover, these organic solvents may be used without mixing with water to disperse or dissolve each component, and then mixed with water. These organic solvents may be used singly or in combinations of two or more thereof.

Water preferably contains impurities in an amount as low as possible from the viewpoint of suppressing contamination of the polished object and the inhibition of the action of other components. For example, water having a total content of transition metal ions of 100 ppb by mass or less is preferable. Here, the purity of water can be increased by, for example, operation such as removal of impurity ions with an ion exchange resin, removal of foreign matter with a filter, distillation, or the like. Specifically, for example, the use of deionized water (ion exchanged water), pure water, ultrapure water, distilled water or the like is preferable. The content of the transition metal ions herein can be measured, for example, by ICP optical emission spectroscopy.

### [Chelating Agent]

The post-CMP cleaning composition according to an embodiment of the present invention preferably contains a chelating agent. When the post-CMP cleaning composition contains the chelating agent, this promotes the adsorption of especially the nitrogen-containing nonionic polymer to the surface of the polished object to further reduce residues. The chelating agent also has the function of adjusting the pH of the post-CMP cleaning composition. Furthermore, the chelating agent can form a chelate with impurities such as metal ions to improve the functions of the nitrogen-containing nonionic polymer and the sulfonic acid group-containing anionic polymer. The chelating agent is preferably an organic compound having at least one phosphoric acid group (—OP(═O)(OH)₂), and more preferably an organic compound having two or more phosphoric acid groups (—OP(═O)(OH)₂). That is, in an embodiment, the post-CMP cleaning composition of the present invention further contains a chelating agent having two or more phosphoric acid groups. Specific examples of the chelating agents include orthophosphoric acid, methyl acid phosphate, ethyl acid phosphate, ethyl glycol acid phosphate, isopropyl acid phosphate, butyl acid phosphate, 2-ethylhexy acid phosphate, pentetic acid, phytic acid, edetic acid, 1-hydroxyethylidene-1,1-diphosphonic acid (hereinafter also referred to as HEDP or etidronic acid), polyphosphoric acid, metaphosphoric acid, hexametaphosphoric acid, phosphonobutane tricarboxylic acid, ethylenediamine tetra(methylene phosphonic acid), diethylenetriamine penta(methylene phosphonic acid), aminotrimethylene phosphonic acid, or salts thereof.

When the post-CMP cleaning composition contains the chelating agent, the content of the chelating agent is not particularly limited, but is preferably 0.003 mass % or more and 0.2 mass % or less, more preferably 0.005 mass % or more and 0.1 mass % or less, and further preferably 0.006 mass % or more and 0.06 mass % or less with respect to the total mass of the post-CMP cleaning composition.

### [Surfactant]

The post-CMP cleaning composition according to the present embodiment may further contain a surfactant. The type of a surfactant is not particularly limited and may be any of nonionic, anionic, cationic and amphoteric surfactants. In an embodiment, the molecular weight of the surfactant can be less than 1,000.

Examples of a nonionic surfactant include the compound other than the above nitrogen-containing nonionic polymer, and examples include an alkyl ether type such as polyoxyethylene lauryl ether and polyoxyethylene oleyl ether; an alkyl phenyl ether type such as polyoxyethylene octyl phenyl ether; an alkyl ester type such as polyoxyethylene laurate; an alkylamine type such as polyoxyethylene laurylamino ether; an alkylamide type such as polyoxyethylene lauramide; a polypropylene glycol ether type such as polyoxyethylene polyoxypropylene ether; an alkanolamide type such as oleic acid diethanolamide; and an allyl phenyl ether type such as polyoxyalkylene allyl phenyl ether. In addition to these examples, propylene glycol, diethylene glycol, monoethanolamine, alcohol ethoxylate, alkylphenol ethoxylate, tertiary acetylene glycol, alkanolamide or the like can also be used as a nonionic surfactant. Note that since the above nitrogen-containing nonionic polymer can have functions as the nonionic surfactants, a separate nonionic surfactant does not need to be added.

Examples of an anionic surfactant include compounds other than the above sulfonic acid group-containing anionic polymer, and include a carboxylic acid type such as sodium myristate, sodium palmitate, sodium stearate, sodium laurate, and potassium laurate; a sulfuric acid ester type such as sodium octylsulfonate; a phosphoric acid ester type such as lauryl phosphate, and sodium lauryl phosphate; and a sulfonic acid type such as dioctyl sulfosuccinate sodium, and sodium dodecylbenzenesulfonate. Note that since the above sulfonic acid group-containing anionic polymer can have a function as the anionic surfactant, a separate anionic surfactant does not need to be added.

Examples of a cationic surfactant include amines such as laurylamine hydrochloride; quaternary ammonium salts such as polyethoxyamine, and lauryltrimethylammonium chloride; and pyridinium salts such as laurylpyridinium chloride.

Examples of an amphoteric surfactant include lecithin, alkylamine oxide, and alkyl betaines or sulfobetaines such as N-alkyl-N,N-dimethyl ammonium betaine.

The surfactants may be used singly or in combinations of two or more thereof. Further, as a surfactant, a commercial product thereof or a synthetic product thereof may also be used.

When the post-CMP cleaning composition contains a surfactant, the lower limit of the content of the surfactant is preferably 0.01 mass % or more, and more preferably 0.05 mass % or more on the basis of the total mass of the post-CMP cleaning composition of 100 mass %. Further, the upper limit of the content of the surfactant in the post-CMP cleaning composition is preferably 5 mass % or less and more preferably 1 mass % or less on the basis of the total mass of the post-CMP cleaning composition of 100 mass %. Note that when the post-CMP cleaning composition contains two or more types of surfactants, the content of surfactants is intended to be the total amount of these types of surfactant.

### <pH of Post-CMP Cleaning Composition>

The pH of the post-CMP cleaning composition according to the present embodiment is preferably less than 7.0. When the pH of the post-CMP cleaning composition is less than 7.0, the potential on the surface of the polished object becomes positive. The anionic polymer containing a negatively charged sulfonic acid group is therefore likely to be adsorbed to the surface of the polished object by electrostatic attraction. This facilitates the protection of surface of the polished object, so that the zeta potential on the surface of the polished object is likely to be negative, and the number of defects further decreases. The pH of the post-CMP cleaning composition is preferably 2 or more and less than 7.0, more preferably 2 or more and 6 or less, further preferably 2.3 or more and 5.5 or less, further more preferably 2.4 or more and less than 5, particularly preferably 2.4 or more and less than 4, and the most preferably 2.4 or more and less than 3.5.

### [pH Adjusting Agent]

Although the pH of the post-CMP cleaning composition can be adjusted with the above sulfonic acid group-containing anionic polymer or chelating agent, the post-CMP cleaning composition may further contain the pH adjusting agent.

The pH adjusting agent is not particularly limited, and known pH adjusting agents that are used in the field of the post-CMP cleaning composition can be used, and, for example, a known acid, base, or a salt thereof and the like other than the above-described chelating agents can be used. Examples of a pH adjusting agent include organic acids, for example, carboxylic acids such as formic acid, acetic acid, propionic acid, butyric acid, valeric acid, caproic acid, enanthic acid, caprylic acid, pelargonic acid, capric acid, lauric acid, myristic acid, palmitic acid, margaric acid, stearic acid, oleic acid, linoleic acid, linolenic acid, arachidonic acid, docosahexaenoic acid, eicosapentaenoic acid, lactic acid, malic acid, citric acid, benzoic acid, phthalic acid, isophthalic acid, terephthalic acid, salicylic acid, gallic acid, mellitic acid, cinnamic acid, oxalic acid, malonic acid, succinic acid, glutaric acid, adipic acid, fumaric acid, maleic acid, aconitic acid, and anthranilic acid, amino acid, sulfonic acid and organic phosphonic acid; inorganic acids such as nitric acid, carbonic acid, hydrochloric acid, hypophosphorous acid, phosphorous acid, phosphonic acid, boric acid, and hydrofluoric acid; hydroxides of alkali metal such as potassium hydroxide (KOH); carbonates of alkali metal such as potassium carbonate (K₂CO₃) and sodium carbonate (Na₂CO₃); hydroxides of group 2 elements (alkaline-earth metals); ammonia (ammonium hydroxide); and organic bases such as a quaternary ammonium hydroxide compound.

As the pH adjusting agent, a synthetic product thereof may be used and a commercial product thereof may also be used. Further, these pH adjusting agents may be used singly or in combinations of two or more thereof.

The content of the pH adjusting agent in the post-CMP cleaning composition may be appropriately selected from such a content leading to a desired pH value of the post-CMP cleaning composition.

Note that as the pH of the post-CMP cleaning composition, a value measured by the method described in the Examples is employed.

### [Other Additives]

The post-CMP cleaning composition according to an embodiment of the present invention may contain another additive (other additives) in an arbitrary proportion as necessary to such an extent that the effects of the present invention are not impaired. However, since components other than the essential components of the post-CMP cleaning composition according to an embodiment of the present invention can cause the presence of foreign matter (residues), no addition of such an additive is desired as long as the additive is unnecessary. Even though the additive is added, it is preferable that the added amount be as small as possible. Examples of the other additives include an antifungal agent (antiseptic agent), dissolved gas, a reducing agent, and an oxidizing agent. The post-CMP cleaning composition according to the present embodiment is preferably acidic. Further, the post-CMP cleaning composition according to the present embodiment contains polymers. Therefore, the post-CMP cleaning composition according to the present embodiment preferably contains an antifungal agent (antiseptic agent) among these. The antifungal agent that can be used for the post-CMP cleaning composition according to the present embodiment is not particularly limited, and can be appropriately selected depending on the polymer type. Specific examples include isothiazoline-based antiseptic agents such as 2-methyl-4-isothiazolin-3-one and 5-chloro-2-methyl-4-isothiazolin-3-one; methyl para-oxybenzoate (methyl para-hydroxybenzoate) and butyl para-oxybenzoate (butyl para-hydroxybenzoate); phenylphenols (2-phenylphenol, 3-phenylphenol, and 4-phenylphenol); unsaturated fatty acids such as sorbic acid; 1,2-alkanediols such as 1,2-pentanediol, 1,2-hexanediol, and 1,2-octanediol; alkyl glyceryl ethers such as 2-ethyhexyl glyceryl ether (ethylhexylglycerin); capric acid; dehydroacetic acid; and phenoxyethanol.

The above antifungal agent may be used singly or in combinations of two or more thereof.

When the post-CMP cleaning composition contains the antifungal agent, the lower limit of the content (concentration) of the antifungal agent is not particularly limited, but is preferably 0.000001 mass % or more, more preferably 0.000002 mass % or more, further preferably 0.000005 mass % or more, and particularly preferably 0.00001 mass % or more with respect to the total mass of the post-CMP cleaning composition. Further, the upper limit of the content (concentration) of the antifungal agent is not particularly limited, but is preferably 3 mass % or less, more preferably 0.6 mass % or less, further preferably 0.3 mass % or less, and particularly preferably 0.06 mass % or less. That is, the content (concentration) of the antifungal agent is preferably 0.000001 mass % or more and 3 mass % or less, more preferably 0.000002 mass % or more and 0.6 mass % or less, further preferably 0.000005 mass % or more and 0.3 mass % or less, and particularly preferably 0.00001 mass % or more and 0.06 mass % or less with respect to the total mass of the post-CMP cleaning composition. If the content is within such a range, effect enough to inactivate or destroy microbes is obtained. Note that if the post-CMP cleaning composition contains two or more types of antifungal agents, the above content means the total amount thereof.

That is, in an embodiment of the present invention, the post-CMP cleaning composition substantially comprises the nitrogen-containing nonionic polymer, the sulfonic acid group-containing anionic polymer, and water as well as at least one selected from the group consisting of the chelating agent, the antifungal agent, the organic solvent, the pH adjusting agent, and the surfactant. In an embodiment of the present invention, the post-CMP cleaning composition substantially comprises the nitrogen-containing nonionic polymer, the sulfonic acid group-containing anionic polymer, and water as well as at least one selected from the group consisting of the chelating agent, the antifungal agent, and the organic solvent. In an embodiment of the present invention, the post-CMP cleaning composition substantially comprises the nitrogen-containing nonionic polymer, the sulfonic acid group-containing anionic polymer, water, and the chelating agent as well as at least one of the antifungal agent and the organic solvent. In an embodiment of the present invention, the post-CMP cleaning composition substantially comprises the nitrogen-containing nonionic polymer, the sulfonic acid group-containing anionic polymer, water, the chelating agent, the antifungal agent, and the organic solvent.

In the embodiment, the sentence “the post-CMP cleaning composition substantially comprises X.” means that the total content of X exceeds 99 mass % (upper limit: 100 mass %) on the basis of the total mass of the post-CMP cleaning composition of 100 mass % (with respect to the post-CMP cleaning composition). The post-CMP cleaning composition preferably consists of X (above total content=100 mass %). For example, the sentence “the post-CMP cleaning composition substantially comprises the nitrogen-containing nonionic polymer, the sulfonic acid group-containing anionic polymer, and water as well as at least one of the chelating agent, the antifungal agent, and the organic solvent.” means that the total content of the nitrogen-containing nonionic polymer, the sulfonic acid group-containing anionic polymer, and water as well as at least one of the chelating agent, the antifungal agent, and the organic solvent exceeds 99 mass % (upper limit: 100 mass %) on the basis of the total mass of the post-CMP cleaning composition of 100 mass % (with respect to the post-CMP cleaning composition). The post-CMP cleaning composition preferably consists of the nitrogen-containing nonionic polymer, the sulfonic acid group-containing anionic polymer, and water as well as at least one of the chelating agent, the antifungal agent, and the organic solvent (above total content=100 mass %).

In order to further improve the effect of removing foreign matter, the post-chemical mechanical polishing cleaning composition (post-CMP cleaning composition) of the present invention preferably contains substantially no abrasive grains. Here, the expression, “contains substantially no abrasive grains” refers to a case in which the content of abrasive grains with respect to the entire post-CMP cleaning composition is less than 0.1 mass % (preferably less than 0.01 mass %). That is, in an embodiment, the content of the abrasive grains in the post-CMP cleaning composition of the present invention is less than 0.1 mass % on the basis of the total mass of the post-CMP cleaning composition of 100 mass %.

In order to further improve the effect of removing foreign matter, the post-CMP cleaning composition according to the present embodiment preferably contains substantially no transition metal ions. Here, the expression, “contains substantially no transition metal ions” refers to a case in which the content of transition metal ions with respect to the entire post-CMP cleaning composition is less than 0.1 mass % (preferably less than 0.01 mass %). That is, in an embodiment, the content of the transition metal ions in the post-CMP cleaning composition of the present invention is less than 0.1 mass % on the basis of the total mass of the post-CMP cleaning composition of 100 mass %.

### <Electrical Conductivity of Post-Chemical Mechanical Polishing Cleaning Composition (Post-CMP Cleaning Composition)>

The electrical conductivity (EC) of the post-CMP cleaning composition according to the present embodiment is not particularly limited, but is preferably 0.20 mS/cm or more, more preferably 0.30 mS/cm or more, and further preferably 0.35 mS/cm or more. The upper limit of the electrical conductivity (EC) of the post-CMP cleaning composition according to the present embodiment is not particularly limited, but is preferably 0.95 mS/cm or less, more preferably 0.90 mS/cm or less, and further preferably 0.60 mS/cm or less. That is, the electrical conductivity (EC) of the post-CMP cleaning composition according to the present embodiment is preferably 0.20 mS/cm or more and 0.95 mS/cm or less, more preferably 0.30 mS/cm or more and 0.90 mS/cm or less, and further preferably 0.35 mS/cm or more and 0.60 mS/cm or less. The electrical conductivity of the post-CMP cleaning composition can be adjusted by changing the types and the amounts of the sulfonic acid group-containing anionic polymer and the pH adjusting agent. The electrical conductivity (EC) of the post-CMP cleaning composition can be measured by the method described in Examples.

<Water Contact Angle of Polished Object During Post-CMP Cleaning Treatment with Post-CMP Cleaning Composition>

As mentioned above, it is inferred that the use of the post-CMP cleaning composition according to the present embodiment enables adsorbing the nitrogen-containing nonionic polymer (and the sulfonic acid group-containing anionic polymer) on the surface of the polished object to desorb residues on the surface of the polished object. It is more specifically inferred that, in the post-CMP cleaning composition according to the present embodiment, the nitrogen-containing nonionic polymer adsorbs to the surface of the poly-Si substrate during the post-CMP cleaning treatment. It is believed that when the nitrogen-containing nonionic polymer has a molecular weight of 2,000 or more, the hydrophilicity of the poly-Si substrate can be sufficiently improved, so that the nitrogen-containing nonionic polymer exhibits the effect of reducing organic residues sufficiently.

When the surface of the polished object has a low water contact angle, this means that the surface has high wettability. It is believed that this is because nitrogen atom moieties of the nitrogen-containing nonionic polymer adsorb to the surface of the polished object to improve the hydrophilicity of the substrate. Accordingly, it is conceivable that high wettability of the surface of the polished object proves the action of the nitrogen-containing nonionic polymer as described in the above mechanism.

Accordingly, the polished object preferably has a lower water contact angle during post-CMP cleaning treatment. For example, when the polished object is a substrate having a film containing polysilicon (poly-Si substrate), it is acceptable for the water contact angle to be 40° or less, and the water contact angle is preferably 35° or less, more preferably 32° or less, further preferably 20° or less, and particularly preferably 15° or less. When the polished object is a substrate having a film containing polysilicon (poly-Si substrate), the lower limit of the water contact angle is not particularly limited, but only has to be 5° or more. The water contact angle of the polished object can be measured by the method described in Examples.

As mentioned above, the post-CMP cleaning composition according to the present embodiment enables reducing the water contact angle of the polished object. According to an embodiment of the present invention, the post-chemical mechanical polishing cleaning composition is therefore provided that has the water contact angle of polysilicon controlled to 5° or more and 400 or less (more preferably 5° or more and 350 or less).

<Zeta Potential of Polished Object During Post-CMP Cleaning Treatment with Post-CMP Cleaning Composition>

As described above, the post-CMP cleaning composition according to the present embodiment contains the sulfonic acid group-containing anionic polymer, so that both the zeta potentials of the surfaces of the polished object and residues (contaminants) can be negatively controlled. It is inferred that the electrostatic repulsion efficiently therefore desorbs residues (contaminants) from the polished object and suppresses the re-adhesion thereof to the polished object.

It is inferred that in the post-CMP cleaning composition according to the present embodiment, the nitrogen-containing nonionic polymer adsorbed to the sulfonic acid group-containing anionic polymer more specifically adsorbs to the surface of a Si₃N₄ substrate during post-CMP cleaning treatment. The sulfonic acid group-containing anionic polymer to which the nitrogen-containing nonionic polymer is adsorbed deteriorates in anionicity. It is believed that this may prevent the sulfonic acid group-containing anionic polymer from negatively charging the Si₃N₄ substrate to consequently inhibit the sulfonic acid group-containing anionic polymer from exhibiting the effect of reducing abrasive grain residues. It is also believed that the nitrogen-containing nonionic polymer adsorbs to the surface of the Si₃N₄ substrate to inhibit the sulfonic acid group-containing anionic polymer from adsorbing to the Si₃N₄ substrate, which may prevent the sulfonic acid group-containing anionic polymer from negatively charging the Si₃N₄ substrate to inhibit the sulfonic acid group-containing anionic polymer from exhibiting the effect of reducing abrasive grain residues. When the nitrogen-containing anionic polymer has a weight-average molecular weight of 2,000 or more and 20,000 or less, the sulfonic acid group-containing anionic polymer can however negatively charge the Si₃N₄ substrate sufficiently, so that the sulfonic acid group-containing anionic polymer can maintain the effect of reducing abrasive grain residues. The measurement of the zeta potential of the Si₃N₄ substrate enables confirming that the sulfonic acid group-containing anionic polymer thus charges the Si₃N₄ substrate negatively.

As mentioned above, the surface of the polished object preferably has a negative zeta potential during post-CMP cleaning treatment. For example, when the polished object is a substrate having a film containing silicon nitride (Si₃N₄ substrate), it is acceptable for the above zeta potential to be −5 mV or less, and the zeta potential is preferably less than −5 mV, more preferably −10 mV or less, further preferably −15 mV or less, particularly preferably −20 mV or less, and the most preferably −25 mV or less. The zeta potential of the surface of the polished object during post-CMP cleaning treatment can be estimated by the method described in Examples.

As mentioned above, with the use of the post-CMP cleaning composition according to the present embodiment, the zeta potential of the polished object can be controlled to a negative value. According to an embodiment of the present invention, there is provided a post-chemical mechanical polishing cleaning composition that has the zeta potential of the surface of the polished object controlled to −50 mV or more and −10 mV or less (more preferably −50 mV or more and −20 mV or less).

### <Method for Producing Post-Chemical Mechanical Polishing Cleaning Composition (Post-CMP Cleaning Composition)>

For example, the method for producing the post-CMP cleaning composition of the present invention can be obtained by stirring and mixing the nitrogen-containing nonionic polymer and the sulfonic acid group-containing anionic polymer, the solvent, and other components as necessary. The temperature at which each component is mixed is not particularly limited, but is preferably 10° C. or higher and 40° C. or lower, and heating may also be performed to increase the rate of dissolution. Further, the mixing time is also not particularly limited.

### <Method for Post-Chemical Mechanical Polishing Cleaning Treatment (Method for Post-CMP Cleaning Treatment; Method for Surface Treatment)>

An embodiment of the present invention is a method for post-chemical mechanical polishing cleaning treatment (herein also referred to as a “method for post-CMP cleaning treatment” or a “method for surface treatment”) comprising subjecting the polished object to the post-chemical mechanical polishing cleaning treatment (herein also referred to as “post-CMP cleaning treatment” or “surface treatment”) with the above post-chemical mechanical polishing cleaning composition (post-CMP cleaning composition). The post-chemical mechanical polishing cleaning treatment (method for post-CMP cleaning treatment) as used herein means a method for reducing residues on the surface of the polished object, which is a method for cleaning in a broad sense.

The method for post-CMP cleaning treatment according to an embodiment of the present invention enables removing residues remaining on the surface of the polished object sufficiently. That is, another embodiment of the present invention provides a method for reducing residues on the surface of the polished object involving subjecting the polished object to the post-chemical mechanical polishing cleaning treatment (post-CMP cleaning treatment) with the above post-chemical mechanical polishing cleaning composition (post-CMP cleaning composition). Another embodiment of the present invention provides a method for post-chemical mechanical polishing cleaning treatment (post-CMP cleaning treatment) involving subjecting the polished object containing silicon-containing material to the post-chemical mechanical polishing cleaning treatment (post-CMP cleaning treatment) with the above post-chemical mechanical polishing cleaning composition (post-CMP cleaning composition) to reduce residues on the surface of the polished object. The silicon-containing material as mentioned here contains at least one selected from the group consisting of silicon oxide, polysilicon, and silicon nitride.

The method for post-CMP cleaning treatment according to an embodiment of the present invention is performed by a method that involves bringing the post-CMP cleaning composition according to the present embodiment into direct contact with a polished object.

Examples of the method for post-chemical mechanical polishing cleaning treatment (post-CMP cleaning treatment) mainly include (I) a method based on rinse polishing treatment, and (II) a method based on cleaning treatment. That is, according to an embodiment of the present invention, the above post-chemical mechanical polishing cleaning treatment (post-CMP cleaning treatment) is preferably performed by rinse polishing treatment or cleaning treatment. That is, the above method for post-chemical mechanical polishing cleaning treatment (post-CMP cleaning treatment) is preferably a rinse polishing treatment method or a cleaning treatment method. Rinse polishing treatment and cleaning treatment are performed for removing foreign matter on a surface of a polished object (particles, metallic contamination, organic residues, pad debris etc.), so as to obtain a clean surface. (I) and (II) above are described as follows.

### (I) Rinse Polishing Treatment

The post-CMP cleaning composition according to the present embodiment is suitably used in rinse polishing treatment. Specifically, the post-CMP cleaning composition according to an embodiment of the present invention can be preferably used as a rinse polishing composition. The rinse polishing treatment is performed on a platen (turn table platen) with a polishing pad attached thereto, after final polishing (finish polishing) of an object to be polished, in order to remove foreign matter on a surface of an object to be polished. At this time, the post-CMP cleaning composition according to the present embodiment is brought into direct contact with the polished object, thereby performing rinse polishing treatment. As a result, foreign matter on the surface of the polished object is removed by frictional force (physical action) applied by the polishing pad and chemical action applied by the post-CMP cleaning composition. Of foreign matter, particularly particles and organic residues are easily removed by physical action. Therefore, in the rinse polishing treatment, through the use of friction with the polishing pad on the platen, particles and organic residues can be effectively removed.

Specifically, the terms “rinse polishing treatment”, “rinse polishing method” and “rinse polishing step” used herein refer to, treatment, a method and a step of reducing residues on a surface of an object to be subjected to post-CMP cleaning treatment with the use of a polishing pad, respectively.

Specifically, the rinse polishing treatment can be performed by placing, after the polishing step, the surface of the polished object on a platen of a polishing apparatus, bringing the polishing pad and the polished semiconductor substrate into contact with each other, and then sliding the polished object and the polishing pad relative to each other while feeding the post-CMP cleaning composition to the contact portion.

As a polishing apparatus, it is possible to use a general polishing apparatus including a holder for holding an object to be polished and a motor or the like having a changeable rotational speed fitted thereto, and a platen to which a polishing pad (polishing cloth) can be attached.

The rinse polishing treatment can also be performed using any of a one-side polishing apparatus and a double-side polishing apparatus. Further, the above polishing apparatus is preferably provided with, in addition to a discharge nozzle for discharging the polishing composition, a discharge nozzle for discharging the post-CMP cleaning composition. Operation conditions for rinse polishing treatment of the polishing apparatus are not particularly limited, and can be appropriately set by persons skilled in the art.

As the polishing pad, a general nonwoven fabric, polyurethane, a porous fluororesin, or the like can be used without any particular limitation. The polishing pad is preferably grooved such that a post-CMP cleaning composition can be stored therein.

Rinse polishing conditions are also not particularly limited. For example, the rotational speed of a platen, and the rotational speed of a head (carrier) are each preferably 10 rpm (0.17 s⁻¹) or more and 100 rpm (1.67 s⁻¹) or less, and pressure (polishing pressure) to be applied to a polished object is preferably 0.5 psi (3.4 kPa) or more and 10 psi (68.9 kPa) or less. A method for feeding the post-CMP cleaning composition to a polishing pad is also not particularly limited. For example, a method for continuously feeding the composition using a pump or the like (discarded after single use) is employed. The feed rate is not limited, but a surface of the polishing pad is preferably covered all the time with the post-CMP cleaning composition, and is preferably 10 mL/minute or more and 5000 mL/minute or less. The rinse polishing time is not particularly limited, either. However, the time is preferably 5 seconds or more and 180 seconds or less.

It is preferable that, after the rinse polishing treatment with the post-CMP cleaning composition according to an embodiment of the present invention, the polished object (object to be subjected to the post-chemical mechanical polishing cleaning treatment) be drawn up and taken out while the post-CMP cleaning composition according to an embodiment of the present invention is sprinkled.

### (II) Cleaning Treatment

The post-CMP cleaning composition according to the present embodiment may also be used in cleaning treatment. Specifically, the post-CMP cleaning composition according to an embodiment of the present invention can be preferably used as a cleaning composition. Cleaning treatment is preferably performed for removing foreign matter on a surface of a polished object (object to be cleaned) after final polishing (finish polishing) of an object to be polished, after the above rinse polishing treatment, or after another rinse polishing treatment using a rinse polishing composition other than the post-CMP cleaning composition of the present invention. Note that the cleaning treatment and the above rinse polishing treatment are classified based on locations where these treatments are performed. The cleaning treatment is preferably surface treatment that is performed at a location not on a platen and is performed after removal of the polished object from the platen. In such cleaning treatment, the post-CMP cleaning composition according to the present embodiment is brought into direct contact with a polished object so as to be able to remove foreign matter on the surface of the object.

Examples of a method for performing cleaning treatment include (i) a method that involves bringing a cleaning brush into contact with one side or both sides of a polished object while holding the polished object, and then running the cleaning brush over the surface of a polished object to be cleaned while feeding the post-CMP cleaning composition to the contact portion, and (ii) a method (dipping mode) that involves immersing a polished object in the post-CMP cleaning composition, and then performing ultrasonic treatment or stirring. With the use of such a method, foreign matter on a surface of a polished object is removed by frictional force applied by a cleaning brush or mechanical force that is generated by ultrasonic treatment or stirring, and chemical action applied by the post-CMP cleaning composition.

In the above method (i), a method for bringing the post-CMP cleaning composition into contact with a polished object, is not particularly limited, and examples thereof include a spinning mode whereby a polished object is rotated at a high speed while the post-CMP cleaning composition is poured from a nozzle onto the polished object, and the spraying mode whereby the post-CMP cleaning composition is sprayed to a polished object to clean the object.

From the viewpoint of being capable of more efficiently performing decontamination within a short time, the cleaning treatment preferably employs the spinning mode and/or the spraying mode, and the same further preferably employs the spinning mode.

Examples of an apparatus for performing such cleaning treatment include a batch-type cleaning apparatus by which a plurality of polished objects housed in a cassette are post-CMP cleaning-treated simultaneously, and a single wafer processing-type cleaning apparatus, by which, a sheet of a polished object is held by a holder for post-CMP cleaning treatment. From the viewpoint of shortening of cleaning time or the like, a method that involves the use of a single wafer processing-type cleaning apparatus is preferable.

Furthermore, an example of an apparatus for performing cleaning treatment is a polishing apparatus provided with a cleaning facility, by which a polished object is scrubbed with a cleaning brush after the polished object is removed from a platen. Through the use of such polishing apparatuses, cleaning treatment can be more efficiently performed for polished objects.

As such a polishing apparatus, it is possible to use a general polishing apparatus including a holder for holding a polished object, a motor having a changeable rotational speed, a cleaning brush, and the like. As a polishing apparatus, any of a one-side polishing apparatus and a double-side polishing apparatus may also be used. Note that when a rinse polishing step is performed after the CMP step, it is more efficient and preferable to perform the cleaning treatment using the same apparatus as that in the rinse polishing step.

The cleaning brush is not particularly limited, but is preferably a resin brush (brush made of resin). The material of the resin brush is not particularly limited, but is preferably PVA (polyvinyl alcohol). The cleaning brush is more preferably a PVA sponge (sponge made of PVA).

Cleaning conditions are also not particularly limited, and can be appropriately set in accordance with the type of a polished object, as well as the type and the amount of residues to be removed. For example, the rotational speed of the cleaning brush is preferably 10 rpm (0.17 s⁻¹) or more and 200 rpm (3.33 s⁻¹) or less, and the rotational speed of a polished object is preferably 10 rpm (0.17 s⁻¹) or more and 100 rpm (1.67 s⁻¹) or less. Pressure (polishing pressure) to be applied to a polished object is preferably 0.5 psi (3.4 kPa) or more and 10 psi (68.9 kPa) or less. A method for feeding the post-CMP cleaning composition to a cleaning brush is also not particularly limited. For example, a method for continuously feeding the composition using a pump or the like (discarded after single use) is employed. The feed rate is not limited, but a cleaning brush and a surface of a polished object are preferably covered all the time with the post-CMP cleaning composition, and is preferably 10 mL/minute or more and 5000 mL/minute or less. The cleaning time is also not particularly limited, but the time for a step using the post-CMP cleaning composition according to an embodiment of the present invention is preferably 5 seconds or more and 180 seconds or less. When the cleaning time is within such range, foreign matter can be more effectively removed.

The temperature of the post-CMP cleaning composition upon cleaning is not particularly limited, and may be generally room temperature. As long as the performance is not impaired, the temperature may also be increased to about 40° C. or higher and 70° C. or lower.

In the above method (ii), conditions for a cleaning method that involves immersion are not particularly limited, and a known technique can be used.

Before post-CMP cleaning treatment is performed according to the above method (I) or (II), cleaning with water may also be performed.

### (Post-Cleaning Treatment)

Further, a post-CMP cleaning treatment method preferably involves further cleaning of the polished object by cleaning treatment after post-CMP cleaning treatment of (I) or (II) above using the post-CMP cleaning composition according to an embodiment of the present invention. This “cleaning treatment” used herein is referred to as post-cleaning treatment. Examples of the post-cleaning treatment include, but are not particularly limited to, a method that involves simply pouring water over a polished object, and a method that involves simply immersing a polished object in water. Further examples thereof include a method that involves, in the manner same as in post-CMP cleaning treatment according to the above-described method (II), bringing a cleaning brush into contact with the one side or both sides of a polished object, while holding the polished object, and then scrubbing the surface(s) of the polished object with the cleaning brush while feeding water or a solution (for example, NH₃ solution) to the contact portion or while feeding water and a solution (for example, NH₃ solution) to the contact portion in any order (feeding water and then feeding the solution, or feeding the solution and then feeding water) (brush cleaning), and a method (dipping mode) that involves immersing a polished object in water, and then performing ultrasonic treatment and stirring. Of these methods, the preferable method involves bringing a cleaning brush into contact with the one side or both sides of a polished object while holding the polished object, and then scrubbing the surface(s) of the polished object with cleaning brush while feeding water or a solution (for example, NH₃ solution) to the contact portion or feeding water and a solution (for example, NH₃ solution) in any order (feeding water and then feeding the solution, or feeding the solution and then feeding water) to the contact portion. Note that regarding apparatuses and conditions of the post-cleaning treatment, the description of the treatment of (II) above can be referred to. Here, as water to be used for the post-cleaning treatment, particularly deionized water is preferably used.

Post-CMP cleaning treatment is performed using the post-CMP cleaning composition according to an embodiment of the present invention, so that residues are exceedingly easily removed. Accordingly, post-CMP cleaning treatment is performed using the post-CMP cleaning composition according to an embodiment of the present invention, and then further cleaning treatment is performed using water, so that residues may be removed extremely well.

Further, a polished object after post-CMP cleaning treatment or after post-cleaning is preferably dried by removing water droplets adhered onto the surface(s) using a spin dryer or the like. Moreover, the surface(s) of a polished object may also be dried by air-blow drying.

### <Method for Producing Semiconductor Substrate>

The post-CMP cleaning treatment method according to an embodiment of the present invention is preferably applied when a polished object is a polished semiconductor substrate. Specifically, according to another embodiment of the present invention, a method for producing a semiconductor substrate is also provided, wherein a polished object is a polished semiconductor substrate, and residues on the surface of the polished semiconductor substrate are reduced by the above post-CMP cleaning treatment method. Accordingly, according to the present invention, provided is a method for producing a semiconductor substrate, wherein the polished object is a polished semiconductor substrate, the method comprising: a polishing step of polishing a semiconductor substrate before polishing using a polishing composition containing abrasive grains, the semiconductor substrate before polishing containing silicon-containing material, for example, at least one selected from the group consisting of silicon oxide, polysilicon, and silicon nitride, to obtain the polished semiconductor substrate; and a post-chemical mechanical polishing cleaning treatment step (herein also referred to as a “post-CMP cleaning treatment step” or a “surface treatment step”) of reducing a residue containing the abrasive grains on the surface of the polished semiconductor substrate using the above post-chemical mechanical polishing cleaning composition (post-CMP cleaning composition).

Detailed descriptions of a semiconductor substrate, to which such a production method is applied, are the same as given for a polished object that is post-CMP cleaning-treated with the above post-CMP cleaning composition.

Further the method for producing a semiconductor substrate is not particularly limited, as long as it comprises a step of post-CMP cleaning-treating a surface of a polished semiconductor substrate using the post-CMP cleaning composition according to an embodiment of the present invention. An example of such a production method is a method having a polishing step and a cleaning step for forming a polished semiconductor substrate. Another example thereof is a method having a rinse polishing step between a polishing step and a cleaning step, in addition to the polishing step and the cleaning step. Each of these steps is as described below.

### [Polishing Step]

A polishing step that can be included in a method for producing a semiconductor substrate is a step for polishing a semiconductor substrate, so as to form a polished semiconductor substrate.

The polishing step is not particularly limited, as long as it is a step for polishing a semiconductor substrate, but the polishing step is a Chemical Mechanical Polishing (CMP) step. Further, the polishing step may comprise a single process or a plurality of processes. Examples of the polishing step comprising a plurality of processes include a polishing step wherein a preliminary polishing process (rough polishing process) is performed and then a finish polishing process is performed, and a polishing step wherein a primary polishing process is performed, a secondary polishing process is performed once or two or more times, and then a finish polishing process is performed. The post-CMP cleaning treatment step using the post-CMP cleaning composition according to the present embodiment is preferably performed after the above finish polishing process.

As the polishing composition, a known polishing composition can be appropriately used in accordance with the property of a semiconductor substrate. The polishing composition is not particularly limited, but for example, the polishing composition containing abrasive grains, a solvent, water-soluble polymer, a pH adjusting agent, or the like can be preferably used. Specific examples of such a polishing composition include a polishing composition containing silicon oxide (for example, colloidal silica), polyvinylpyrrolidone, ammonia, and water.

The abrasive grains may be any of inorganic particles, organic particles, and organic-inorganic composite particles. Specific examples of the inorganic particles include particles comprising a metallic oxide such as silicon oxide, alumina, ceria, or titania; silicon nitride particles; silicon carbide particles; and boron nitride particles. Specific examples of the organic particles include polymethyl methacrylate (PMMA) particles. Further, as the abrasive grains, commercial products thereof or synthetic products thereof may also be used. Moreover, the abrasive grains may be surface-modified. The abrasive grains may be used singly or in combinations of two or more thereof.

The lower limit of the average primary particle size of the abrasive grains is preferably 10 nm or more, more preferably 15 nm or more, further preferably 20 nm or more, and further preferably 30 nm or more. If the lower limit is within such a range, high removal rate can be maintained, the abrasive grains can therefore be suitably used in the rough polishing process. Further, the upper limit of the average primary particle size of the abrasive grains is preferably 200 nm or less, more preferably 150 nm or less, and further preferably 100 nm or less. In some aspects, the average primary particle size may be 75 nm or less, 60 nm or less, or 50 nm or less. If the average primary particle size is within such a range, defect production on the surface of the object to be polished after the polishing can be further controlled. Note that, for example, the average primary particle size of the abrasive grains is calculated based on the specific surface area of the abrasive grains measured by the BET method.

The lower limit of the average secondary particle size of the abrasive grains is preferably 15 nm or more, more preferably 30 nm or more, further preferably 40 nm or more, further more preferably 50 nm or more, and particularly preferable 60 nm or more. If the lower limit is within such a range, high removal rate can be maintained. Further, the upper limit of the average secondary particle size of the abrasive grains is preferably 300 nm or less, more preferably 200 nm or less, further preferably 150 nm or less, further more preferably 100 nm or less, and particularly preferably 80 nm or less. If the upper limit is within such a range, defect production on the surface of the object to be polished after the polishing can be further controlled. The average secondary particle size of the abrasive grains can be measured by dynamic light scattering. For example, the average secondary particle size can be measured using the model “FPAR-1000” manufactured by Otsuka Electronics Co., Ltd. or a counterpart thereof.

When the polishing composition is used as a polishing liquid as it is, the content of the abrasive grains is preferably 0.1 mass % or more, more preferably 0.4 mass % or more, and further preferably 1.0 mass % or more with respect to the polishing composition. An increase in the content of the abrasive grains improves the removal rate. Further, when polishing composition is used as the polishing liquid as it is, from the viewpoint of scratch prevention and the like, the content of the abrasive grains is usually and suitably 10 mass % or less, preferably 5 mass % or less, more preferably 3 mass % or less, and further preferably 2 mass % or less. It is also preferable to reduce the content of the abrasive grains from the viewpoint of economic efficiency. Note that when two or more types of abrasive grains are used in combination, the above content refers to the total content of the two or more types of abrasive grains.

Since the pH adjusting agent and the solvent are the same as specified in the above items [pH adjusting agent] and [solvent], the description is omitted here.

As a polishing apparatus, it is possible to use a general polishing apparatus including a holder for holding an object to be polished and a motor or the like having a changeable rotational speed fitted thereto, and a platen to which a polishing pad (polishing cloth) can be attached. As a polishing apparatus, any of a one-side polishing apparatus and a double-side polishing apparatus may also be used.

As the polishing pad, a general nonwoven fabric, polyurethane, a porous fluororesin, or the like can be used without any particular limitation. The polishing pad is preferably grooved such that a polishing liquid can be stored therein.

Polishing conditions are also not particularly limited, either. For example, the rotational speed of a platen and the rotational speed of a head are each preferably 10 rpm (0.17 s⁻¹) or more and 100 rpm (1.67 s⁻¹) or less, and the pressure (polishing pressure) applied to an object to be polished is preferably 0.5 psi (3.4 kPa) or more and 10 psi (68.9 kPa) or less. A method for feeding a polishing composition to a polishing pad is not particularly limited, either. For example, a method that involves feeding a polishing composition continuously using a pump or the like can be employed (discarded after single use). The feed rate is not limited, but a surface of the polishing pad is preferably covered all the time with the polishing composition, and it is preferably 10 mL/minute or more and 5000 mL/minute or less. The polishing time is also not particularly limited, either. However, for the step of using the polishing composition, it is preferably 5 seconds or more and 180 seconds or less.

### <Post-Chemical Mechanical Polishing Cleaning Treatment Step (Post-CMP Cleaning Treatment Step)>

The post-CMP cleaning treatment step refers to a step of reducing a residue on the surface of the polished object using the post-CMP cleaning composition according to the present embodiment. In a method for producing a semiconductor substrate, after a rinse polishing step, a cleaning step as the post-CMP cleaning treatment step may be performed, the rinse polishing step alone or the cleaning step alone may be performed.

### (Rinse Polishing Step)

The rinse polishing step may be provided between the polishing step and the cleaning step in the method for producing a semiconductor substrate. The rinse polishing step is a step for reducing foreign matter on a surface of a polished object (polished semiconductor substrate) by the post-CMP cleaning treatment method (rinse polishing treatment method) according to an embodiment of the present invention.

Detailed descriptions of a rinse polishing method employed in the rinse polishing step are as given for the above rinse polishing treatment.

### (Cleaning Step)

The cleaning step may be provided following the polishing step or the rinse polishing step in a method for producing a semiconductor substrate. The cleaning step is a step for reducing foreign matter on a surface of a polished object (polished semiconductor substrate) by the post-CMP cleaning treatment method (cleaning method) according to an embodiment of the present invention.

Detailed descriptions for a cleaning method employed in the cleaning step are as given for the above cleaning method.

The embodiments of the present invention are described in detail above, but are explanatory and illustrative only, and are not limited. The scope of the present invention should be obviously construed on the basis of the attached claims.

The present invention includes the following aspects and embodiments.
[1] A post-chemical mechanical polishing cleaning composition, comprising: a sulfonic acid group-containing anionic polymer; and a nitrogen-containing nonionic polymer having a weight-average molecular weight of 2,000 or more and 20,000 or less;
[2] the post-chemical mechanical polishing cleaning composition according to the above [1], comprising the nitrogen-containing nonionic polymer at 10 mass ppm or more and 1 mass % or less with respect to the total mass of post-chemical mechanical polishing cleaning composition;
[3] the post-chemical mechanical polishing cleaning composition according to the above [1] or [2], comprising the sulfonic acid group-containing anionic polymer at 0.1 mass ppm or more and 1000 mass ppm or less with respect to the total mass of post-chemical mechanical polishing cleaning composition;
[4] the post-chemical mechanical polishing cleaning composition according to any of the above [1] to [3], wherein the water contact angle of polysilicon is controlled to 400 or less;
[5] the post-chemical mechanical polishing cleaning composition according to any of the above [1] to [4], wherein the zeta potential of the surface of silicon nitride is controlled to −20 mV or less;
[6] the post-chemical mechanical polishing cleaning composition according to any of the above [1] to [5], comprising substantially no abrasive grains;
[7] a method for post-chemical mechanical polishing cleaning treatment, comprising: surface-treating a polished object using the post-chemical mechanical polishing cleaning composition according to any of the above [1] to [6], the polished object comprising at least one selected from the group consisting of silicon oxide, polysilicon, and silicon nitride, to reduce a residue on the surface of the polished object;
[8] the method for post-chemical mechanical polishing cleaning treatment according to the above [7], wherein the method is a rinse polishing treatment method or a cleaning treatment method; and
[9] a method for producing a semiconductor substrate,
   wherein a polished object is a polished semiconductor substrate, the method comprising:
   a polishing step of polishing a semiconductor substrate before polishing using a polishing composition containing abrasive grains, the semiconductor substrate before polishing containing at least one selected from the group consisting of silicon oxide, polysilicon, and silicon nitride, to obtain the polished semiconductor substrate; and
   a post-chemical mechanical polishing cleaning treatment step of reducing a residue on the surface of the polished semiconductor substrate using the post-chemical mechanical polishing cleaning composition according to any of the above [1] to [6].

### EXAMPLES

The present invention will be described in more detail using the following Examples and Comparative Examples, but the technical scope of the present invention is not limited to only the following Examples. Note that unless otherwise specified, “%”, “ppm” and “part(s)” refer to “mass %”, “mass ppm” and “parts by mass”, respectively. Further, in the following Examples, unless otherwise specified, operation was performed under conditions of room temperature (25° C.)/relative humidity of 40% RH or more and 50% RH or less.

### [Polymer Preparations]

The following nitrogen-containing nonionic polymers and sulfonic acid group-containing anionic polymers were prepared.

### “Nitrogen-Containing Nonionic Polymer”

Polyvinylpyrrolidone; weight-average molecular weight: 1,000
Polyvinylpyrrolidone; weight-average molecular weight: 10,000
Polyvinylpyrrolidone; weight-average molecular weight: 20,000
Polyvinylpyrrolidone; weight-average molecular weight: 30,000
N-ethylpyrrolidone

### “Sulfonic Acid Group-Containing Anionic Polymer”

Sodium salt of copolymer of acrylic acid and 2-acrylamido-2-methylpropane sulfonic acid (hereinafter also referred to as a “(acrylic acid/sulfonic acid)copolymer”) (product name: ARON A-6012 (TOAGOSEI CO., LTD.)); Weight-average molecular weight: 12,000
Polyacrylic acid; Weight-average molecular weight: 15,0000

The weight-average molecular weights of the above polymers were measured by the following method.

### [Measurement of Weight-Average Molecular Weight (Mw) of Polymer]

As the weight-average molecular weights (Mw) of the polymers, the values of the weight-average molecular weights (in terms of polyethylene glycol) measured by gel permeation chromatography (GPC) were used. The weight-average molecular weights were measured using the following apparatuses and conditions:
GPC apparatus: manufactured by SHIMADZU CORPORATION
Model: Prominence+ELSD detector (ELSD-LTII)
Column: VP-ODS (manufactured by SHIMADZU CORPORATION)
Mobile phase A: MeOH
   B: Acetic acid 1% aqueous solution
Flow rate: 1 mL/min
Detector: ELSD temp. 40° C., Gain 8, N₂GAS 350 kPa
Oven temperature: 40° C.
Amount injected: 40 μL.

### [Measurement of pH of Post-CMP Cleaning Composition]

The pH of the post-CMP cleaning composition (liquid temperature: 25° C.) was confirmed using a pH meter (manufactured by HORIBA, Ltd., Product name: LAQUA (registered trademark)).

### [Electrical Conductivity of Post-CMP Cleaning Composition]

The electrical conductivity (EC) of post-CMP cleaning composition was measured with a desktop electrical conductivity meter (manufactured by HORIBA, Ltd., model number: DS-71 LAQUA(registered trademark)).

### [Preparation of Post-CMP Cleaning Composition]

### Example 1

A post-CMP cleaning composition A1 was prepared by mixing polyvinylpyrrolidone having a weight-average molecular weight of 10,000 as a nitrogen-containing nonionic polymer; an (acrylic acid/sulfonic acid) copolymer having a weight-average molecular weight of 12,000 as a sulfonic acid group-containing anionic polymer; water (deionized water) as a solvent; 1-hydroxyethane-1,1-diphosphonic acid (hereinafter “HEDP”) (product name: Dequest(registered trademark) 2010EL (Italmatch Japan Ltd.)) as a chelating agent; ammonia (product name: EL Ammonia Solution (KANTO CHEMICAL CO., INC.)) as a pH adjusting agent; and an antifungal agent (antiseptic agent) (San-ai bac R-30 (produced by SAN-AI OBBLI CO., LTD.)) with stirring at 25° C. for 5 minutes.

The post-CMP cleaning composition A1 contained the nitrogen-containing nonionic polymer at a content of 125 mass ppm with respect to the total mass of the post-CMP cleaning composition A1; the sulfonic acid group-containing anionic polymer at a content of 100 mass ppm with respect to the total mass of the post-CMP cleaning composition A1; the chelating agent at a content of 150 mass ppm with respect to the total mass of the post-CMP cleaning composition A1; the pH adjusting agent at a content such that the post-CMP cleaning composition A1 had a pH of 3.1; and the antifungal agent at a content of 0.000025 mass % with respect to the total mass of the post-CMP cleaning composition A1.

### Examples 2 to 14 and Comparative Examples 1 to 6

Post-CMP cleaning compositions A2 to A14 and post-CMP cleaning compositions B1 to B6 were prepared in the same way as in Example 1 except that the types and/or the contents of the nitrogen-containing nonionic polymer and the sulfonic acid group-containing anionic polymer were changed as described in Table 1 and Table 2.

In Tables 1 and 2, the nitrogen-containing nonionic polymer was expressed as an “N-containing nonionic polymer”, and the (acrylic acid/sulfonic acid) copolymer was expressed as an “AA/SA copolymer”.

In Table 1 and Table 2, “PVP” indicates polyvinylpyrrolidone. In Table 1 and Table 2, the description “- (hyphen)” means that the compound is not added, and the “ppm” as the unit of concentration of the compounds means “mass ppm”.

### [Preparation of Polished Object]

Polished objects that had been polished in the following chemical mechanical polishing (CMP) step were prepared.

### (CMP Step)

As objects to be polished, provided were (1) a silicon wafer having a polycrystalline silicon film with a thickness of 5000 Å on the surface (herein also referred to as a poly-Si substrate or a polysilicon substrate) (300 mm, blanket wafer, produced by D&X Co., Ltd.) and (2) a silicon wafer having a silicon nitride (Si₃N₄) film with a thickness of 2500 Å on the surface (also referred to as a Si₃N₄ substrate) (300 mm, blanket wafer, produced by ADVANTEC CO., LTD.). Note that 1 Å=0.1 nm.

The poly-Si substrate and the Si₃N₄ substrate provided above were polished under the follow conditions using a polishing composition (composition; 5-fold dilution of slurry containing 10 mass % colloidal silica (average primary particle size: 35 nm, average secondary particle size: 70 nm), 0.25 mass % polyvinylpyrrolidone, and 0.33 mass % ammonia (ammonium hydroxide)). Note that 1 rpm=0.017 s⁻¹.

### <Polishing Apparatus and Polishing Conditions>

Polishing apparatus: single side polishing apparatus for CMP of 300 mm wafers, Reflexion LK, manufactured by Applied Materials, Inc.
Polishing pad: manufactured by Fujibo Holdings, Inc., foamed polyurethane pad H800
Conditioner (dresser): nylon brush (manufactured by 3M Company)
Polishing pressure: 2.0 psi (1 psi=6894.76 Pa, the same applies to the following)
Rotational speed of platen: 80 rpm
Rotational speed of head: 80 rpm
Feed of polishing composition: free flowing
Feed rate of polishing composition: 200 mL/minute
Polishing time: 60 seconds.

### [Post-Chemical Mechanical Polishing Cleaning Treatment (Post-CMP Cleaning Treatment)]

### (Rinse Polishing)

After polishing of the surface of each object to be polished in the above CMP step, the polished object was removed from the platen. Next, within the same polishing apparatus, the polished object was set on another platen, and then under the following conditions, the surface of the polished object was subjected to rinse polishing treatment using the post-CMP cleaning compositions A1 to A14 prepared in Examples 1 to 14 above and the post-CMP cleaning compositions B1 to B6 prepared in Comparative Examples 1 to 6 above.

### <Rinse Polishing Apparatus and Rinse Polishing Conditions>

Polishing apparatus: single side polishing apparatus for CMP of 300 mm wafers, Reflexion LK, manufactured by Applied Materials, Inc.
Polishing pad: manufactured by Fujibo Holdings, Inc., foamed polyurethane pad H800 Conditioner (dresser): nylon brush (manufactured by 3M Company)
Polishing pressure: 1.0 psi
Rotational speed of platen: 80 rpm
Feed of post-CMP cleaning composition: free flowing
Feed rate of post-CMP cleaning composition: 300 mL/minute
Polishing time: 60 seconds.

### (Post Cleaning)

After rinse polishing treatment, the surfaces were subjected to brush cleaning for 20 seconds using an aqueous 0.3 mass % NH₃ solution, followed by cleaning for 40 seconds with deionized water, and thereby obtaining rinse-polished objects that had been rinsed and polished.

### [Evaluation 1: Measurement of the Number of Residues]

The polished objects obtained in the above item [Preparation of polished object] were subjected to the cleaning treatment by the method described in the above item [Post-chemical mechanical polishing cleaning treatment (post-CMP cleaning treatment)] to obtain the poly-Si substrate and the Si₃N₄ substrate, followed by evaluation of the numbers of residues on the surfaces of the poly-Si substrate and the Si₃N₄ substrate. Specifically, the number of residues (abrasive grain residues) was measured with an optical inspector Surfscan (registered trademark) SP5 manufactured by KLA Corporation. The number of residues (abrasive grain residues) having diameters of 40 nm or more was counted on the remaining portion other than a portion 5 mm wide from the peripheral end (portion spreading from 0 mm to 5 mm in width when the peripheral end was defined as 0 mm) of one side of Si₃N₄ substrate, and the number of residues (abrasive grain residues) having diameters of 70 nm or more was counted on the remaining portion other than a portion 5 mm wide from the peripheral end of one side of the poly-Si substrate. Then, the number of abrasive grain residues and the number of organic residues on the above polished poly-Si substrate and Si₃N₄ substrate were measured by SEM observation using a Review SEM RS6000 manufactured by Hitachi High-Tech Corporation. First, 100 residues existing on the remaining portion other than the portion 5 mm wide from the peripheral end of one side of each of the polished poly-Si substrate and the polished Si₃N₄ substrate were sampled by the SEM observation. Then, the residue types of the 100 sampled residues (abrasive grains or organic residues) were distinguished by visual SEM observation, and the numbers of the abrasive grain residues (SiO₂ residues) and the organic residues (pad debris, polymers, and the like) were confirmed respectively. The following Table 1 and Table 2 show the results. After the rinse polishing using the post-CMP cleaning compositions A1 to A14 and B1 to B6, the numbers of abrasive grain residues having a diameter of 70 nm or more on the poly-Si substrate were 0, and the numbers of organic residues on the Si₃N₄ substrate were less than 5. Since all of the post-CMP cleaning compositions A1 to A14 and B1 to B6 had equivalent performances, detailed results of evaluation were omitted.

It is preferable that the number of abrasive grain residues (SiO₂ residues) be as small as possible. For example, it is acceptable for the number of abrasive grain residues having a diameter of 40 nm or more on the Si₃N₄ substrate to be 800 or less, and the number is preferably 250 or less, more preferably 200 or less, further preferably 100 or less, particularly preferably 70 or less, and the most preferably 50 or less.

It is also preferable that the number of organic residues (pad debris, polymers, and the like) be as small as possible. For example, it is acceptable for the number of organic residues (pad debris, polymers, and the like) having a diameter of 70 nm or more on the poly-Si substrate to be 800 or less, and the number is preferably 500 or less, more preferably 250 or less, further preferably 200 or less, particularly preferably 150 or less, and the most preferably 100 or less.

It is preferable that the total number of residues be as small as possible, the total number of residues being the total of the number of abrasive grain residues having a diameter of 40 nm or more on the Si₃N₄ substrate and the number of organic residues (pad debris, polymers, and the like) having a diameter of 70 nm or more on the poly-Si substrate. For example, it is acceptable for the total of the number of abrasive grain residues having a diameter of 40 nm or more on the Si₃N₄ substrate and the number of organic residues having a diameter of 70 nm or more on the poly-Si substrate to be 1,000 or less, and the total is preferably 600 or less, more preferably 500 or less, further preferably 300 or less, particularly preferably 200 or less, and the most preferably 150 or less.

### [Evaluation 2: Measurement of Water Contact Angle (Wettability)]

After the rinse polishing treatment using the post-CMP cleaning compositions A1 to A14 and B1 to B6, prepared in the above Examples 1 to 14 and Comparative Examples 1 to 6, the Si₃N₄ substrates were measured for the water contact angle.

The substrates (poly-Si substrates) used in the above item [Preparation of polished object] were cut into 60 mm squares to prepare sample substrates. Subsequently, the substrates were polished in the same way as in the method described in the above item [Preparation of polished object] to obtain polished objects. Then, each of the polished objects was attached to a platen in the following polishing apparatus and subjected to rinse polishing treatment under the following conditions using the post-CMP cleaning compositions A1 to A14 and B1 to B6, prepared in the above Examples 1 to 14 and Comparative Examples 1 to 6.

### <Rinse Polishing Apparatus and Rinse Polishing Treatment Conditions (for Evaluating Wettability)>

Polishing apparatus: Lapping machine EJ-380IN-C manufactured by Engis Japan Corporation
Polishing pad: manufactured by Fujibo Holdings, Inc., foamed polyurethane pad H800
Conditioner (dresser): nylon brush (manufactured by 3M Company)
Polishing pressure: 1.0 psi
Rotational speed of platen: 60 rpm
Rotational speed of head: 60 rpm
Feed of post-CMP cleaning composition: free flowing
Feed rate of post-CMP cleaning composition: 100 mL/minute
Polishing time: 60 seconds.

After the rinse polishing treatment as mentioned above, moisture on the surfaces was removed with an air shower without post-cleaning treatment to obtain a rinse-polished object. Then, the water contact angles were measured by the θ/2 method. The contact angle evaluation apparatus DMo-501 manufactured by Kyowa Interface Science Co., Ltd. was used for the measurement. The following Table 1 and Table 2 show the results.

### [Evaluation 3: Measurement of Zeta Potential]

The Si₃N₄ substrates being rinse-polished with the above post-CMP cleaning compositions A1 to A14 and B1 to B6, prepared in Examples 1 to 14 and Comparative Examples 1 to 6, were measured for zeta potential.

The substrates (Si₃N₄ substrates) used in the above item [Preparation of polished object] were cut into 30 mm squares to prepare sample substrates. Subsequently, the sample substrates were polished in the same way as in the method described in the above item [Preparation of polished object] to obtain polished objects as objects to be measured. Then, each of the above objects to be measured was attached to a zeta potential measuring apparatus for solid, SurPASS 3, (zeta potential meter). Then, each of the post-CMP cleaning compositions A1 to A14 and B1 to B6, prepared in Examples 1 to 14 and Comparative Examples 1 to 6, was passed through the above object to be measured to measure the object to be measured for zeta potential (mV). The value was defined as the zeta potential of the wafer being rinse-polished. The following Table 1 and Table 2 show the results.

TABLE 1

| | Sulfonic acid group- | | Nitrogen-containing | | | | | | | | |
|---|---|---|---|---|---|---|---|---|---|---|---|
| | containing anionic | | nonionic polymer or | | Physical properties | | | | Evaluation | | |
| | polymer or alternative | | alternative compound | | | | | Water | | | The |
| | compound thereof | | thereof | | | Electrical | Zeta | contact | Abrasive | | total |
| | | Concen- | | Concen- | | conduc- | potential | angle on | grain | Organic | number of |
| | | tration | | tration | pH | tivity | of SiN | poly-Si | residues | residues | residues |
| | Compound | [ppm] | Compound | [ppm] | [—] | [mS/cm] | [mV] | [°] | residues | residues | residues |
| Example | AA/SA | 100 | PVP having | 125 | 3.1 | 0.4 | −31 | 32 | 25 | 157 | 182 |
| 1 | copolymer | | molecular | | | | | | | | |
| | | | weight of 10000 | | | | | | | | |
| Example | AA/SA | 100 | PVP having | 2500 | 3.0 | 0.4 | −29 | 12 | 26 | 114 | 140 |
| 2 | copolymer | | molecular | | | | | | | | |
| | | | weight of 10000 | | | | | | | | |
| Example | AA/SA | 100 | PVP having | 5000 | 3.0 | 0.4 | −25 | 12 | 19 | 104 | 123 |
| 3 | copolymer | | molecular | | | | | | | | |
| | | | weight of 10000 | | | | | | | | |
| Example | AA/SA | 1 | PVP having | 125 | 3.0 | 0.4 | −25 | 32 | 28 | 132 | 160 |
| 4 | copolymer | | molecular | | | | | | | | |
| | | | weight of 10000 | | | | | | | | |
| Example | AA/SA | 10 | PVP having | 125 | 3.1 | 0.4 | −30 | 32 | 8 | 117 | 125 |
| 5 | copolymer | | molecular | | | | | | | | |
| | | | weight of 10000 | | | | | | | | |
| Example | AA/SA | 1000 | PVP having | 125 | 3.0 | 0.8 | −26 | 32 | 7 | 258 | 265 |
| 6 | copolymer | | molecular | | | | | | | | |
| | | | weight of 10000 | | | | | | | | |
| Example | AA/SA | 10 | PVP having | 2500 | 3.0 | 0.4 | −25 | 12 | 32 | 154 | 186 |
| 7 | copolymer | | molecular | | | | | | | | |
| | | | weight of 10000 | | | | | | | | |
| Example | AA/SA | 1 | PVP having | 2500 | 3.0 | 0.4 | −24 | 12 | 28 | 78 | 106 |
| 8 | copolymer | | molecular | | | | | | | | |
| | | | weight of 10000 | | | | | | | | |
| Example | AA/SA | 100 | PVP having | 2500 | 3.0 | 0.4 | −20 | 9 | 156 | 54 | 210 |
| 9 | copolymer | | molecular | | | | | | | | |
| | | | weight of 20000 | | | | | | | | |
| Example | AA/SA | 100 | PVP having | 10 | 3.0 | 0.4 | −30 | 39 | 12 | 324 | 336 |
| 10 | copolymer | | molecular | | | | | | | | |
| | | | weight of 10000 | | | | | | | | |
| Example | AA/SA | 100 | PVP having | 10000 | 3.0 | 0.4 | −22 | 12 | 58 | 187 | 245 |
| 11 | copolymer | | molecular | | | | | | | | |
| | | | weight of 10000 | | | | | | | | |
| Example | AA/SA | 0.1 | PVP having | 2500 | 3.0 | 0.4 | −23 | 12 | 68 | 154 | 222 |
| 12 | copolymer | | molecular | | | | | | | | |
| | | | weight of 10000 | | | | | | | | |
| Example | AA/SA | 10000 | PVP having | 2500 | 3.0 | 0.4 | −25 | 12 | 19 | 567 | 586 |
| 13 | copolymer | | molecular | | | | | | | | |
| | | | weight of 10000 | | | | | | | | |
| Example | AA/SA | 100 | PVP having | 50000 | 3.0 | 0.4 | −15 | 12 | 674 | 134 | 808 |
| 14 | copolymer | | molecular | | | | | | | | |
| | | | weight of 10000 | | | | | | | | |

TABLE 2

| | Sulfonic acid group- | | Nitrogen-containing | | | | | | | | |
|---|---|---|---|---|---|---|---|---|---|---|---|
| | containing anionic | | nonionic polymer or | | Physical properties | | | | Evaluation | | |
| | polymer or alternative | | alternative compound | | | | | Water | | | The |
| | compound thereof | | thereof | | | Electrical | Zeta | contact | Abrasive | | total |
| | | Concen- | | Concen- | | conduc- | potential | angle on | grain | Organic | number of |
| | | tration | | tration | pH | tivity | of SiN | Poly-Si | residues | residues | residues |
| | Compound | [ppm] | Compound | [ppm] | [—] | [mS/cm] | [mV] | [°] | residues | residues | residues |
| Comparative | AA/SA | 100 | PVP having | 2500 | 3.0 | 0.4 | −32 | 42 | 18 | 1023 | 1041 |
| Example | copolymer | | molecular | | | | | | | | |
| 1 | | | weight of 1000 | | | | | | | | |
| Comparative | AA/SA | 100 | PVP having | 5000 | 3.0 | 0.4 | −12 | 9 | 1857 | 24 | 1881 |
| Example | copolymer | | molecular | | | | | | | | |
| 2 | | | weight of 30000 | | | | | | | | |
| Comparative | AA/SA | 100 | N- | 2500 | 3.0 | 0.4 | −30 | 63 | 23 | 2068 | 2091 |
| Example | copolymer | | Ethylpyrrolidone | | | | | | | | |
| 3 | | | having | | | | | | | | |
| | | | molecular | | | | | | | | |
| | | | weight of 113 | | | | | | | | |
| Comparative | — | — | PVP having | 2500 | 3.0 | 0.4 | 10 | 12 | 3543 | 135 | 3678 |
| Example | | | molecular | | | | | | | | |
| 4 | | | weight of 10000 | | | | | | | | |
| Comparative | Polyacrylic | 100 | PVP having | 2500 | 3.0 | 0.4 | −2 | 13 | 2375 | 187 | 2562 |
| Example | acid | | molecular | | | | | | | | |
| 5 | | | weight of 10000 | | | | | | | | |
| Comparative | Polyacrylic | 100 | — | — | 3.0 | 0.4 | −18 | 65 | 342 | 3046 | 3388 |
| Example | acid | | | | | | | | | | |
| 6 | | | | | | | | | | | |

As is clear from above Tables 1 and 2, it was found that the post-CMP cleaning compositions A1 to A14 of Examples 1 to 14 were able to reduce residues on the surfaces of the polished objects containing silicon-containing material as compared with the post-CMP cleaning composition B1 to B6 of Comparative Examples 1 to 6.

The present application is based on the Japanese patent application No. 2024-168596 filed on Sep. 27, 2024, and the disclosed contents thereof is incorporated herein by reference in their entirety.

1. A post-chemical mechanical polishing cleaning composition, comprising: a sulfonic acid group-containing anionic polymer; and a nitrogen-containing nonionic polymer having a weight-average molecular weight of 2,000 or more and 20,000 or less.

2. The post-chemical mechanical polishing cleaning composition according to claim 1, comprising the nitrogen-containing nonionic polymer at 10 mass ppm or more and 1 mass % or less with respect to the total mass of post-chemical mechanical polishing cleaning composition.

3. The post-chemical mechanical polishing cleaning composition according to claim 1, comprising the sulfonic acid group-containing anionic polymer at 0.1 mass ppm or more and 1000 mass ppm or less with respect to the total mass of post-chemical mechanical polishing cleaning composition.

4. The post-chemical mechanical polishing cleaning composition according to claim 1, wherein a water contact angle of polysilicon is controlled to 5° or more and 40° or less.

5. The post-chemical mechanical polishing cleaning composition according to claim 1, wherein zeta potential of a surface of silicon nitride is controlled to −50 mV or more and −20 mV or less.

6. The post-chemical mechanical polishing cleaning composition according to claim 1, comprising substantially no abrasive grains.

7. A method for post-chemical mechanical polishing cleaning treatment, comprising: surface-treating a polished object using the post-chemical mechanical polishing cleaning composition according to claim 1, the polished object comprising at least one selected from the group consisting of silicon oxide, polysilicon, and silicon nitride, to reduce a residue on a surface of the polished object.

8. The method for post-chemical mechanical polishing cleaning treatment according to claim 7, wherein the method is a rinse polishing treatment method or a cleaning treatment method.

9. A method for producing a semiconductor substrate,
wherein a polished object is a polished semiconductor substrate, the method comprising:
a polishing step of polishing a semiconductor substrate before polishing using a polishing composition comprising abrasive grains, the semiconductor substrate before polishing comprising at least one selected from the group consisting of silicon oxide, polysilicon, and silicon nitride, to obtain a polished semiconductor substrate; and
a post-chemical mechanical polishing cleaning treatment step of reducing a residue on a surface of the polished semiconductor substrate using the post-chemical mechanical polishing cleaning composition according to claim 1.
